(19) United States
(12) Patent Application Publication
(10) Pub. No.: US 2022/0108891 A1
(43) Pub. Date: Apr. 7, 2022

(54) MODULAR ZONE CONTROL FOR A PROCESSING CHAMBER

(71) Applicant: Applied Materials, Inc., Santa Clara, CA (US)

(72) Inventors: Zubin Huang, Santa Clara, CA (US); Manjunath Veerappa Chobari Patil, Bengaluru (IN); Diwakar Kedlaya, San Jose, CA (US); Truong Van Nguyen, San Jose, CA (US); Pavan Kumar Murali Kumar, Bangalore (IN); Subrahmanyam Veerisetty, Bangalore (IN); Venkata Sharat Chandra Parimi, Sunnyvale, CA (US); Fang Ruan, Milpitas, CA (US)

(73) Assignee: Applied Materials, Inc., Santa Clara, CA (US)

(21) Appl. No.: 17/064,389

(22) Filed: Oct. 6, 2020

(51) Int. Cl. H01L 21/033; H01J 37/32; C23C 16/50; C23C 16/455; H01L 21/02; C23C 16/04

(52) U.S. Cl. CPC H01L 21/0332; H01J 37/32724; C23C 16/50; C23C 16/45589; H01J 2237/3323; H01L 21/02274; C23C 16/042; H01J 2237/3321; H01J 37/32449

(57) ABSTRACT

Exemplary semiconductor processing chambers may include a faceplate assembly characterized by at least one surface defining a number of voids. Each void is configured to receive an interchangeable thermal body that can be selected from multiple interchangeable thermal bodies. Exemplary semiconductor processing chambers may also include a gas box characterized by movable members. Each movable member is configured to engage a delivery port and is movable to provide flow control for a gas being delivered to the processing volume through a gas flow path. Zoned flow and/or temperature control may be provided by the faceplate assembly, the gas box, or both.

### TECHNICAL FIELD

The present technology relates to components and apparatuses for semiconductor manufacturing. More specifically, the present technology relates to processing chamber distribution components and other semiconductor processing equipment.

### BACKGROUND

Integrated circuits are made possible by processes that produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features, such as apertures, for providing materials in a way that may increase uniformity. However, this may limit the ability to tune recipes for on-substrate adjustments.

Thus, there is a need for improved systems and methods that can be used to produce high quality devices and structures. These and other needs are addressed by the present technology.

### SUMMARY

Exemplary semiconductor processing chambers may include a chamber body defining a processing volume, a pedestal disposed at least partly within the processing volume, and a faceplate assembly coupled to the chamber body above the pedestal. The faceplate assembly includes at least one surface defining a plurality of voids. Each void is configured to receive an interchangeable thermal body that can be selected from multiple interchangeable thermal bodies. At least one of the interchangeable thermal bodies engages with at least one of the voids.

Exemplary semiconductor processing chambers may include a chamber body defining a processing volume, a pedestal disposed at least partly within the processing volume, and a gas box. The gas box may be disposed above a faceplate and the pedestal. The gas box includes an upper plate defining delivery ports and a lower plate defining a gas flow path. The gas box further includes movable members. Each movable member is configured to engage a delivery port and is movable to provide flow control for a gas being delivered to the processing volume through the recessed channel and the gas flow path.

Exemplary interchangeable thermal bodies for engagement with a modular faceplate assembly may include a plug having a specific thermal emissivity selected from plugs having varied thermal emissivities, a plug having a specific thermal mass selected from plugs having varied thermal masses, and/or a thermal contact. Exemplary movable members for a gas box may include screws accessible through access ports defined by the lower plate of the gas box. An exemplary gas box may also include a top cover coextensive with the recessed channel to secure gas in the recessed channel and a removable bottom cover at least coextensive with the access ports.

Some embodiments of the technology encompass semiconductor processing methods. A semiconductor processing method using modular zone control may include providing a modular faceplate assembly and providing a gas box. A zoned portion of the processing volume is controlled by engaging at least one interchangeable thermal body with the modular faceplate assembly, by adjusting at least one movable member engageable with a delivery port in the gas box, or both. The semiconductor substrate can then be processed using the modular faceplate assembly and the gas box.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary semiconductor processing system according to some embodiments of the present technology.

FIG. 3 shows a schematic partial cross-sectional view of an exemplary processing chamber according to some embodiments of the present technology.

FIG. 4 shows a schematic perspective view of an exemplary faceplate assembly according to some embodiments of the present technology.

FIG. 5 shows a schematic top plan view of another exemplary faceplate assembly according to some embodiments of the present technology.

FIG. 6A and FIG. 6B show a schematic perspective view and a schematic magnified view, respectively, of an interchangeable thermal body according to some embodiments of the present technology.

FIG. 7 shows a schematic, partially exploded view of another exemplary faceplate assembly according to some embodiments of the present technology.

FIG. 8 shows a schematic perspective view of an additional exemplary faceplate assembly according to some embodiments of the present technology.

FIG. 9A and FIG. 9B show a schematic top view and a schematic side view, respectively, of an interchangeable thermal body according to some embodiments of the present technology.

FIG. 10 shows a schematic, exploded view of an exemplary gas box according to some embodiments of the present technology.

FIG. 11A and FIG. 11B shows a schematic cross-sectional view and a magnified cross-sectional view, respectively, of an exemplary gas box according to some embodiments of the present technology.

FIG. 12 shows a flowchart of a method for processing a semiconductor substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Chemical vapor deposition (CVD) processes may energize one or more constituent precursors to facilitate film formation on a substrate. Such deposition processes include both thermal CVD processes and plasma-enhanced CVD processes. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. The precursors may be distributed through one or more components within the chamber, which may produce a radial or lateral uniformity of delivery to provide increased formation or removal at the substrate surface.

As device features reduce in size, tolerances across a substrate surface may be reduced, and material property differences across a film may affect device realization and uniformity. Many chambers include a characteristic process signature, which may produce non-uniformity across a substrate. Temperature differences, flow pattern uniformity, and other aspects of processing may impact the films on the substrate, creating film property differences as well as differences across the substrate for materials produced or removed. Adjusting processes at different regions of the substrate, such as for in-plane distortion issues and other film property challenges, may be difficult, and many conventional technologies have been limited in the adjustments available.

The present technology overcomes these challenges by utilizing chamber components that facilitate zone-based control of the processing environment near a semiconductor substrate being processed in a semiconductor processing system. These chamber components can include, as an example, a modular faceplate assembly. The modular faceplate assembly can provide a thermal boundary that is dynamically tunable relative to different portions of the semiconductor substrate. The modular faceplate assembly can be altered through selection and use of interchangeable thermal bodies. The faceplate assembly can be installed to provide a faceplate that compensates for thermal non-uniformity of the substrate, or creates thermal non-uniformity as desired.

As another example, the chamber components can include a gas box that provides dynamic zone control for gases being introduced into a processing chamber near a semiconductor substrate. The gas profile provided by the gas box can be changed by setting any or all of a number of movable members that engage gas delivery ports distributed around the gas box.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

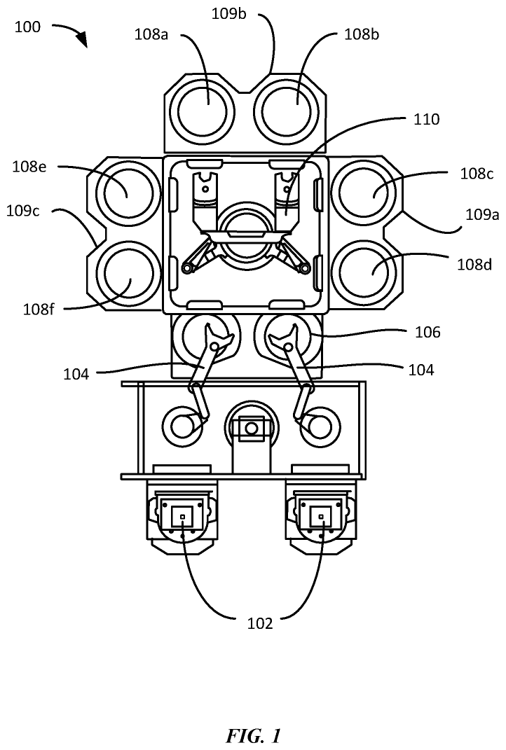

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

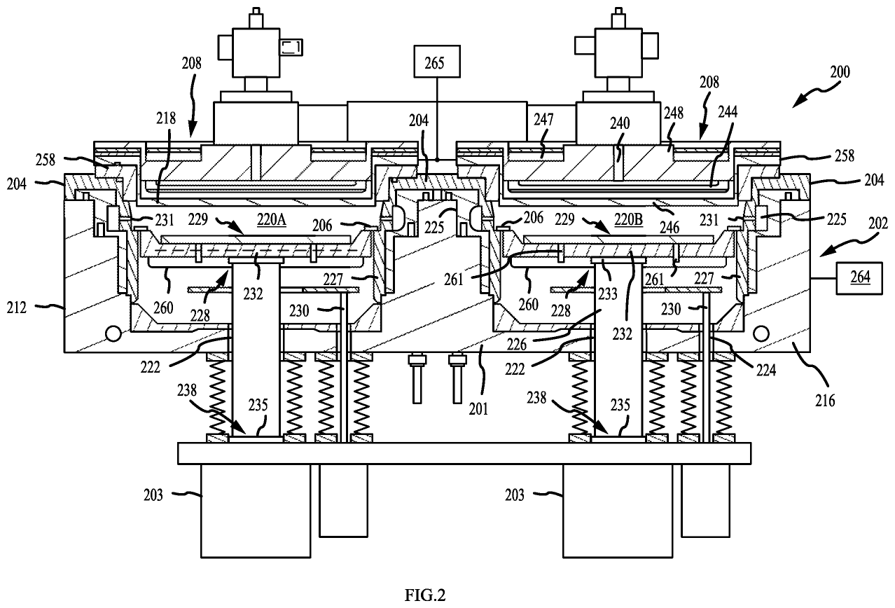

FIG. 2 shows a schematic cross-sectional view of an exemplary semiconductor processing system 200 according to some embodiments of the present technology. System 200 may illustrate a pair of processing chambers 108 that may be fitted in one or more of tandem sections 109 described above, and which may include faceplates and/or gas boxes according to embodiments of the present technology. The system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240, which may deliver reactant and cleaning precursors through a dual-channel showerhead 218 into the processing region 220B. The dual-channel showerhead 218 may include an annular base plate 248 having a blocker plate 244 disposed intermediate to a faceplate assembly 246. A faceplate assembly multiple components may be referred to herein as a faceplate assembly or a faceplate. A radio frequency (“RF”) source 265 may be coupled with the dual-channel showerhead 218, which may power the dual-channel showerhead 218 to facilitate generating a plasma region between the faceplate assembly 246 of the dual-channel showerhead 218 and the pedestal 228 in a system designed for plasma-enhanced CVD. In some embodiments, the RF source may be coupled with other portions of the chamber body 202, such as the pedestal 228. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

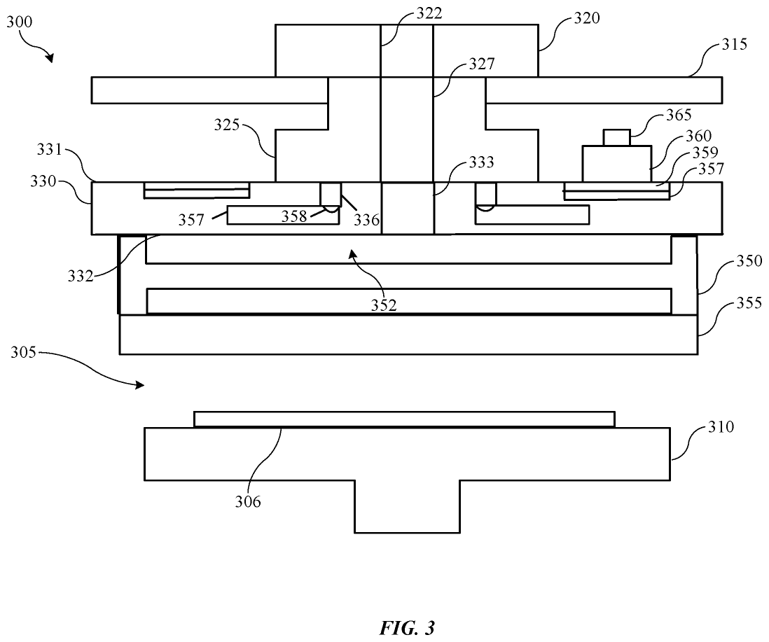

FIG. 3 shows a schematic partial cross-sectional view of an exemplary semiconductor processing chamber 300 according to some embodiments of the present technology. FIG. 3 may include one or more components discussed above with regard to FIG. 2, and may illustrate further details relating to that chamber. Chamber 300 is understood to include any feature or aspect of system 200 discussed previously in some embodiments. The chamber 300 may be used to perform semiconductor processing operations including deposition of hardmask materials as previously described, as well as other deposition, removal, and cleaning operations. Chamber 300 may show a partial view of a processing region of a semiconductor processing system, and may not include all of the components.

As noted, FIG. 3 may illustrate a portion of a processing chamber 300. The chamber 300 may include a number of lid stack components, which may facilitate delivery or distribution of materials through the processing chamber into a processing region 305, such as where a substrate 306 may be positioned on a pedestal 310, for example. A chamber lid plate 315 may extend across one or more plates of the lid stack and may provide structural support for components, such as a remote plasma unit illustrated previously for system 200. The lid plate 315 may provide access, such as through an aperture to an internal volume of processing chamber 300. An inlet manifold 320 may be positioned on the lid plate and may provide coupling with a remote plasma unit, which may provide precursors or plasma effluents for chamber cleaning or other processing operations. Inlet manifold 320 may define a central aperture 322, which may extend about a central axis of the chamber or inlet manifold. Processing chamber 300 may also include an insulator 325, which may electrically or thermally separate the inlet manifold from other lid stack components. Insulator 325 may also define a central aperture 327, which may be axially aligned with the central aperture 322 of the inlet manifold 320. Processing chamber 300 may also include a gas box 330, on which the insulator may be positioned.

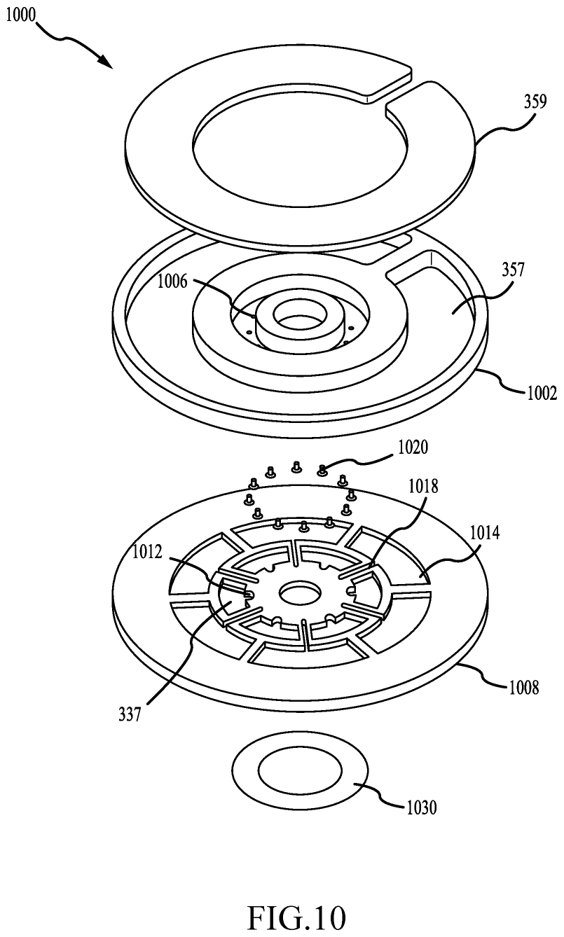

Gas box 330 may be characterized by a first surface 331 and a second surface 332 that may be opposite the first surface. The first surface may be the outer surface of an upper plate and the second surface may be the outer surface of a lower plate as described below with respect to FIG. 10. The gas box may define a central aperture 333, which may extend fully through the gas box from the first surface to the second surface. The central aperture 333 may be axially aligned with the central aperture of the inlet manifold 320, and may be axially aligned with the central aperture of the insulator 325. The apertures may define a channel, which may be at least partially used to deliver effluents. Gas box 330 may also define one or more channels that may be fluidly accessed through the gas box, and may allow multiple precursors to be delivered through the lid stack in a variety of flow profiles.

For example, gas box 330 may also define one or more delivery ports 336. Delivery ports 336 may be deliver precursor gas into gas flow paths 337 through the gas box. Flow may then extend to a blocker plate and faceplate, which may maintain additional or diluted flow, and which may affect deposition, etch, or cleaning operations within the chamber processing region. Some deposition or etch materials may cause non-uniformity at the substrate surface, which may cause profile or film property changes across the substrate. By allowing additional precursor delivery at a radially outward location, additional precursors may be delivered, which may bolster growth, such as by delivering additional processing precursors. Additionally, one or more diluents may be delivered to reduce deposition or etch processes at locations across the substrate.

The delivery ports 336 may be distributed in a radial pattern about the gas box, which may follow a general shape or profile of the recessed channel 357. Movable members 358 may be engageable with delivery ports 336. Movable members 358 may be, as examples, screws or force-fit, movable plugs. When multiple zones are included, such as illustrated, flow paths 337 may be distributed to facilitate delivery from the zones. Gas box 330 may include additional features. Recessed channel 357 may allow a cooling fluid to be flowed about the gas box, and which may allow additional temperature control. As illustrated, the recessed channel 357 may be defined in the first surface 331 of the gas box 330, and a top cover 359 may extend about the recessed channel to form a hermetic seal. Recessed channel 357 may extend about central aperture 333, and may also be concentric with the central aperture.

Gas box 330 may include at least one plate, and may include two, three, four, or more plates depending on the features formed. As illustrated, gas box 330 may include at least two plates, which may allow multiple paths to be formed to further distribute precursors. Semiconductor processing chamber 300 may also include additional components in some embodiments, such as a blocker plate 350, and a faceplate assembly 355 coupled to the chamber body. Blocker plate 350 may define a number of apertures that may operate as a choke to increase radial diffusion to improve uniformity of delivery. Blocker plate 350 may be a first location through the lid stack where precursors delivered to the central aperture of the gas box and precursors delivered to the annular channel of the gas box may intermix. As illustrated, a volume 352 may be formed or defined between the gas box 330 and the blocker plate 350. Volume 352 may be fluidly accessible from both central aperture 333 and a plurality of outlet apertures. Precursors delivered into the zone may then at least partially mix or overlap before continuing through the lid stack. By allowing an amount of mixing prior to contacting the substrate surface, an amount of overlap may be provided, which may produce a smoother transition at the substrate, and may limit an interface from forming on a film or substrate surface. Faceplate assembly 355 may then deliver precursors to the processing region, which may be at least partially defined from above by the faceplate assembly.

To provide an additional precursor flow path through the annular channel, additional components may be incorporated to facilitate operation. For example, an isolator 360 may be included to isolate connection components from the gas box. Gas box 330 may be electrically coupled with faceplate assembly 355, which, in a plasma-enhanced CVD system, may be utilized as a plasma-generating electrode. In such a system, components of the lid stack may operate as a plasma-generating electrode, such as a hot electrode. Consequently, delivery components, which may be at electrical ground, may benefit from an isolator decoupling associated components from the gas box. An isolation valve 365 may also be included in the system, and may be included between piping from a gas panel and the chamber. The valve may prevent materials from back streaming into the fluid lines during process operations in which an additional fluid may not be flowed into the processing region through the annular channel.

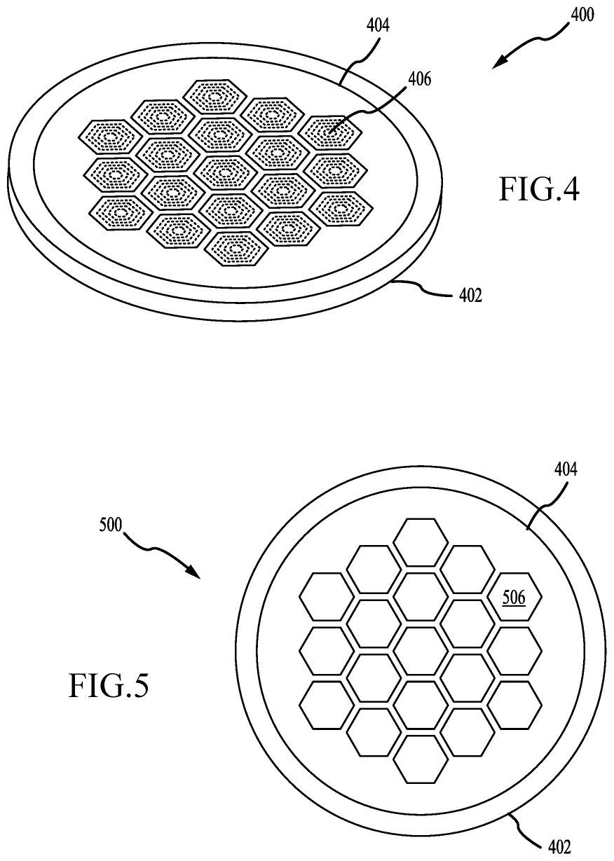

FIG. 4 shows a schematic perspective view of an exemplary faceplate assembly 400 according to some embodiments of the present technology. Faceplate assembly 400 includes a base 402, a spacer 404 and multiple interchangeable thermal bodies. More particularly, faceplate assembly 400 includes nineteen hexagonal plugs 406 designed to tune local, thermal, emissivity values for the faceplate assembly. Plugs 406 are interchangeable. Thus, multiple plugs for each of a number of emissivity values can be moved around in order to create a faceplate with a desired thermal emissivity profile. A plug having a specific thermal emissivity can be selected from plugs having varied thermal emissivities.

FIG. 5 shows a schematic top plan view of an exemplary faceplate assembly 500 according to some embodiments of the present technology. Faceplate assembly 500 is similar to faceplate assembly 400, except that the thermal bodies are removed, leaving hexagonal voids 506. In the case of faceplate assembly 500, the voids are defined in both upward and downward facing surfaces of base 402 and in spacer 404.

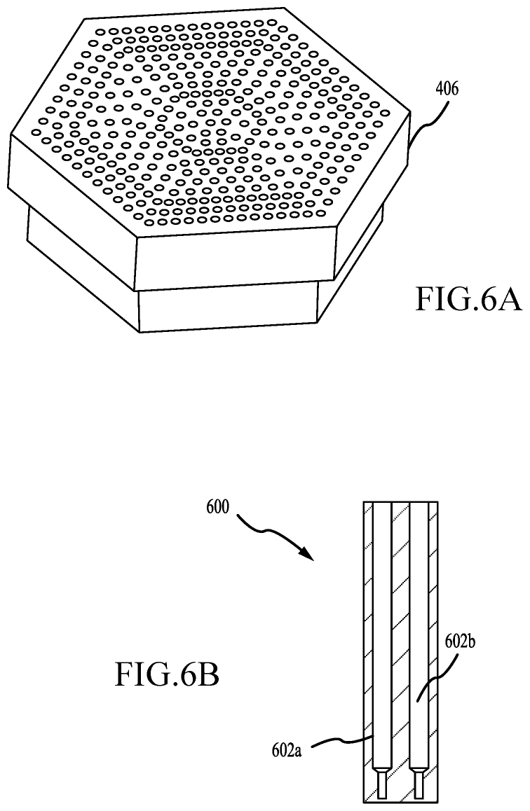

FIG. 6A and FIG. 6B show a schematic perspective view and a schematic magnified view, respectively, of an interchangeable thermal body according to some embodiments of the present technology. More specifically, FIG. 6A illustrates emissivity plug 406, removed from the faceplate assembly. Plug 406 includes multiple outlet apertures. The number, size, and length of these apertures can be adjusted to create plugs with different thermal emissivity values. FIG. 6B is a schematic, magnified, cross-section 600 of a portion of plug 406. FIG. 6B shows two, identical outlet apertures, 602a and 602b. These outlet apertures narrow towards the bottom of the faceplate. The sizes, narrowing point, and length of outlet apertures can be adjusted when plugs are produced to provide plugs with multiple thermal emissivity values. A plug can be selected for a specific void from various plugs of differing emissivity values in order to control thermal emissivity at the corresponding location within a processing chamber, whether the chamber is designed for thermal CVD or plasma-enhanced CVD.

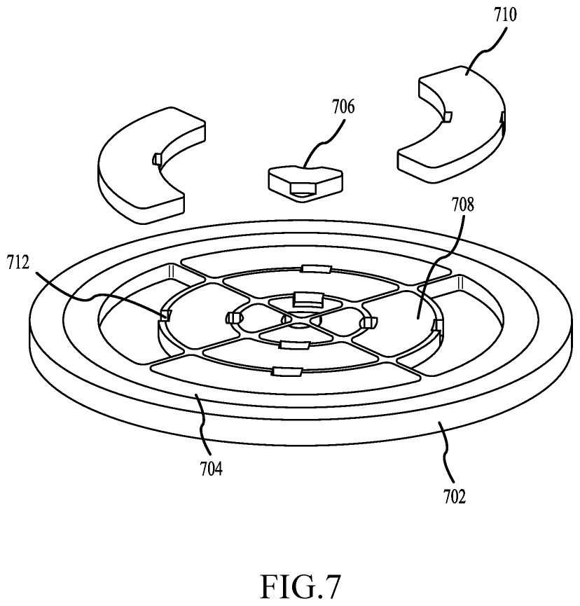

FIG. 7 shows a schematic, partially exploded view of another exemplary faceplate assembly 700 according to some embodiments of the present technology. Faceplate assembly 700 includes a base 702, a spacer 704 and multiple interchangeable thermal bodies. More particularly, faceplate assembly 700 includes twelve, removable thermal mass plugs arranged in three concentric zones. These thermal mass plugs are designed to tune local, thermal, mass values for the faceplate assembly. The thermal mass plugs have matching voids in the top surface of base 702 as well as in spacer 704.

Interchangeable thermal mass plugs 706 of faceplate assembly 700 reside in a first concentric zone, interchangeable thermal mass plugs 708 reside in a second concentric zone, and interchangeable thermal mass plugs 710 reside in a third concentric zone of the faceplate. A plug having a specific thermal mass can be selected from plugs having varied thermal masses for a void in a given zone. Various plugs of differing thermal mass that match the voids in each the zones can be used in order to control thermal mass at the corresponding locations within a processing chamber used for thermal or plasma-enhanced CVD. Flow impact of changing a thermal mass plug is kept to a minimum by small, permanent holes on the faceplate assembly such as hole 712.

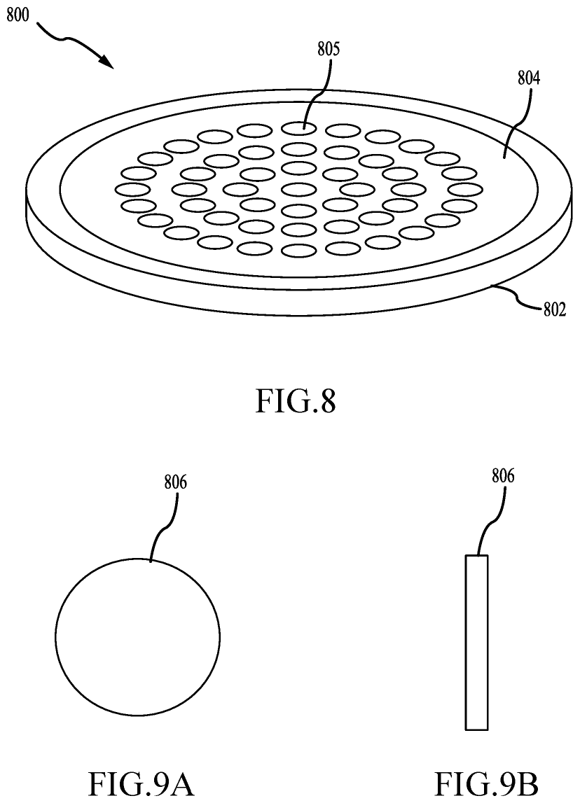

FIG. 8 shows a schematic perspective view of an exemplary faceplate assembly 800 according to some embodiments of the present technology. Faceplate assembly 800 includes a base 802, and a spacer 804. The spacer includes multiple identical voids 805 that extend through both its upward and downward facing surfaces. Each of these voids is configured to accept an interchangeable thermal body, in this case a thermal contact that is placed directly on the surface of the base of the faceplate assembly, on top of any grooves that are typically present. The thermal contact modifies thermal loss from the faceplate assembly to a blocker plate.

FIG. 9A and FIG. 9B show a schematic top view and a schematic side view, respectively, of an interchangeable thermal contact according to some embodiments of the present technology. FIG. 9A is a top plan view and FIG. 9B is a side view of thermal contact 806. Thermal contact 806 can be made of aluminum and the thermal contacts are added or removed as needed to increase or decrease local heat loss and/or gas flow in a chamber used for thermal or plasma-enhanced CVD.

FIG. 10 shows a schematic, exploded view of an exemplary gas box 1000 according to some embodiments of the present technology. Gas box 1000 includes an upper plate 1002 defining a recessed channel 357 and a plurality of delivery ports 1006. Gas box 1000 also includes a lower plate 1008 and multiple gas flow paths. Each gas flow path is connected to a delivery port. The gas flow paths are divided into twelve zones. Gas flow paths 337 are each connected to delivery port adjacent to an access port such as access port 1012. Gas flow paths 1014 are each fluidly connected to a delivery channel such as delivery channel 1016, which is in turn fluidly connected to a delivery port adjacent to an access port such as access port 1018. Movable members 1020, in this example, screws, each engage a delivery port and can be accessed through an access port. The screws can be adjusted to provide flow control for gasses in the corresponding zone. These movable members facilitate quickly engaging and disengaging zones when processing changes are made.

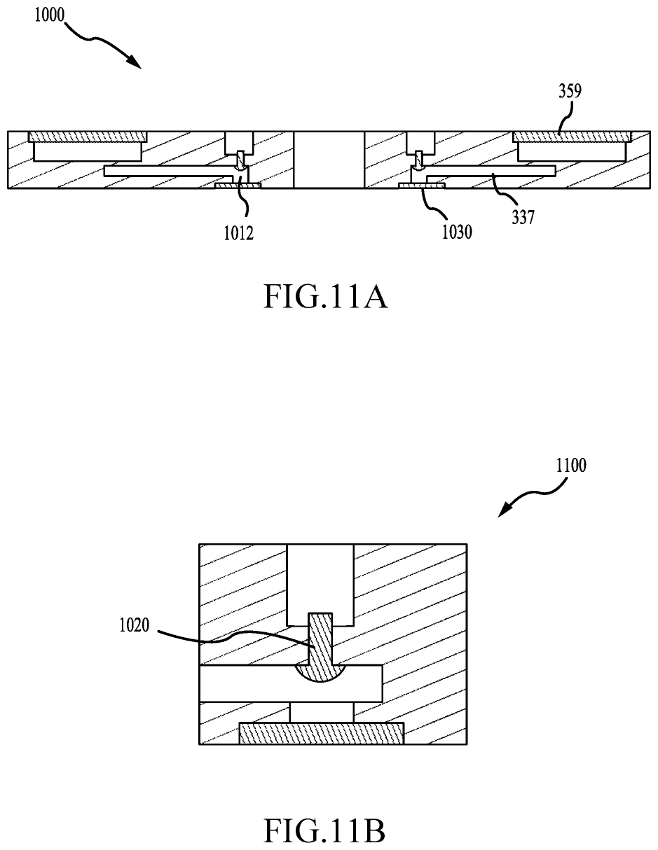

Gas box 1000 further includes top cover 359 coextensive with the recessed channel 1004 to secure the recessed channel. Gas box 1000 also includes an optional removable bottom cover 1030 to protect the screws 1020 during operation while allowing access for adjustment. Bottom cover 1030 is therefore at least coextensive with the screws but can extend beyond them. The gas flow paths in gas box 1000 can be used to purge the processing volume with an inert gas such as helium while reducing local deposition rates in a thermal or plasma-enhanced CVD process. FIG. 11A and FIG. 11B show a schematic cross-sectional view and a magnified cross-section 1100 of assembled gas box 1000, respectively.

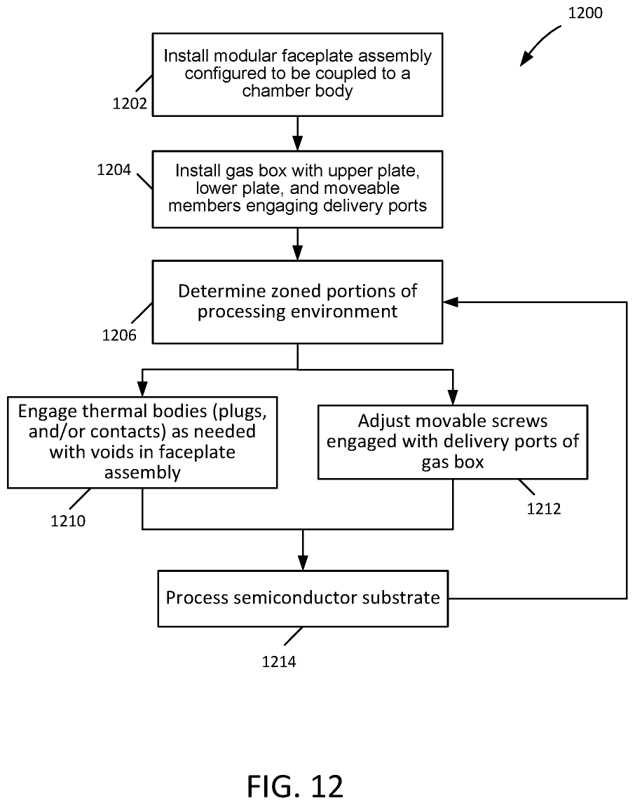

FIG. 12 shows a flowchart of a method for processing a semiconductor substrate according to some embodiments of the present technology. Method 1200 may be performed in one or more chambers, including chambers previously described herein. Method 1200 may make use of the faceplate assembly and/or gas box previously described herein, along with the other components shown. Method 1200 may include a number of optional operations, which may or may not be specifically associated with some embodiments of the present technology. For example, many of the operations are described in order to provide a broader scope of the structures use, but are not critical to the technology, or may be performed by alternative methodology as would be readily appreciated.

In operation 1202 of method 1200, a modular faceplate assembly with interchangeable thermal bodies is installed as configured to be coupled to the chamber body. In operation 1204 of the method, a gas box with upper plate, lower plate, and movable members as previously described is installed in the semiconductor processing system. In operation 1206, a determination is made as to how to zone portions of the processing environment. This determination can be made, as examples, by computerized modeling and mapping, or based on past, documented, configurations of this same or similar systems.

Operations 1210 and 1212 may be carried out concurrently, one after the other, or one may be omitted. In operation 1201, thermal bodies such as plugs or contacts are engaged with voids in the faceplate assembly as needed. In operation 1212, movable screws engaged with delivery ports of the gas box or adjusted as needed. In operation 1214, the semiconductor substrate is processed using the zone control established by the gas box and/or the modular faceplate assembly. When a processing changes made, or a different substrate is processed, a determination can be made again at operation 1206 and the configuration of the gas box and/or faceplate assembly can be changed.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups. The words “coupled”, “connected”, “connectable”, “disposed” and similar terms may refer to a direct connection or placement between components, or a connection or placement with or among intervening components. Terms such as “above”, “below”, “upward”, “downward”, “top”, and “bottom” are meant to refer to relative positions when observing the figures in a normal orientation and do not necessarily imply actual positioning in a physical system.

What is claimed is:

1. A semiconductor processing chamber comprising:
a chamber body defining a processing volume;
a pedestal disposed at least partly within the processing volume; and
a faceplate assembly coupled to the chamber body above the pedestal in the processing volume, the faceplate assembly comprising:
at least one surface defining a plurality of voids, each void configured to receive an interchangeable thermal body of a plurality of interchangeable thermal bodies; and
at least one of the plurality of interchangeable thermal bodies engaged with at least one of the plurality of voids.

2. The semiconductor processing chamber of claim 1 wherein the interchangeable thermal body comprises a plug having a specific thermal emissivity selected from a plurality of plugs having varied thermal emissivities.

3. The semiconductor processing chamber of claim 1 wherein the interchangeable thermal body comprises a plug having a specific thermal mass selected from a plurality of plugs having varied thermal masses.

4. The semiconductor processing chamber of claim 1 wherein the interchangeable thermal body comprises a thermal contact.

5. The semiconductor processing chamber of claim 1 further comprising a gas box disposed above the faceplate and the pedestal, the gas box comprising:
an upper plate defining a plurality of delivery ports;
a lower plate defining a gas flow path; and
a plurality of movable members, each movable member configured to engage a delivery port of the plurality of delivery ports, each movable member being movable to provide flow control for a gas being delivered to the semiconductor processing chamber through the gas flow path.

6. The semiconductor processing chamber of claim 5 wherein the lower plate further defines a plurality of access ports for the plurality of movable members, the upper plate further defines a recessed channel, and the gas box further comprises:
a top cover coextensive with the recessed channel; and
a removable bottom cover at least coextensive with the plurality of access ports.

7. The semiconductor processing chamber of claim 5 wherein the plurality of movable members comprises a plurality of screws accessible through a plurality of access ports further defined by the lower plate.

8. A method of processing a semiconductor substrate using modular zone control, the method comprising:
providing a modular faceplate assembly configured to be coupled to a chamber body above a pedestal to support the semiconductor substrate in a processing volume;
providing a gas box configured to be disposed above the faceplate assembly and the pedestal;
controlling a zoned portion of the processing volume by engaging at least one interchangeable thermal body with the modular faceplate assembly, adjusting at least one movable member engageable with a delivery port in the gas box, or both; and
processing the semiconductor substrate using the modular faceplate assembly and the gas box.

9. The method of claim 8 wherein controlling the zoned portion comprises engaging the at least one thermal body comprising a plug having a specific thermal emissivity selected from a plurality of plugs having varies thermal emissivities.

10. The method of claim 8 wherein controlling the zoned portion comprises engaging the at least one thermal body comprising a plug having a specific thermal mass selected from a plurality of plugs having varied thermal masses.

11. The method of claim 8 wherein controlling the zoned portion comprises engaging the at least one thermal body comprising a thermal contact.

12. The method of claim 8 wherein the gas box comprises:
an upper plate defining a plurality of delivery ports;
a lower plate defining a gas flow path; and
a plurality of movable members, each movable member configured to engage a delivery port of the plurality of delivery ports, each movable member being movable to provide flow control for a gas being delivered to the processing volume through the gas flow path.

13. The method of claim 12 wherein controlling the zoned portion comprises adjusting at least one movable member engageable with the delivery port in the gas box and the movable member comprises a screw.

14. The method of claim 13 further comprising removing a removable bottom cover in order to obtain access to the at least one movable member.

15. The method of claim 14 wherein the at least one movable member comprises a screw.

16. A semiconductor processing chamber gas box comprising:
an upper plate defining a plurality of delivery ports;
a lower plate defining a gas flow path; and
a plurality of movable members, each movable member configured to engage a delivery port of the plurality of delivery ports, each movable member being movable to provide flow control for a gas being delivered to the semiconductor processing chamber through the gas flow path.

17. The semiconductor processing chamber gas box of claim 16 wherein the lower plate further defines a plurality of access ports for the plurality of movable members and the semiconductor processing chamber gas box further comprises a removable bottom cover at least coextensive with the plurality of access ports.

18. The semiconductor processing chamber gas box of claim 17 wherein the plurality of movable members comprises a plurality of screws accessible through a plurality of access ports further defined by the lower plate.

19. The semiconductor processing chamber gas box of claim 16 wherein the upper plate further defines a recessed channel, and the semiconductor processing chamber gas box further comprises a top cover coextensive with the recessed channel.

20. The semiconductor processing chamber gas box of claim 16 wherein the gas flow path comprises a plurality of gas flow paths and further wherein at least one of the plurality of gas flow paths includes or is fluidly connected to a delivery channel.
